(19) United States
(12) Patent Application Publication
(10) Pub. No.: US 2026/0354131 A1
(43) Pub. Date: Nov. 5, 2026

(54) POLY-SIC WAFER WITH STRUCTURAL FEATURES AND HEAT TRANSFER CHARACTERISTICS

(71) Applicant: Microchip Technology Inc., Chandler, AZ (US)

(72) Inventors: Steve Nagel, Chandler, AZ (US); Bomy Chen, Newark, CA (US)

(73) Assignee: Microchip Technology Inc., Chandler, AZ (US)

(21) Appl. No.: 19/227,577

(22) Filed: Jun. 4, 2025

Related U.S. Application Data
(60) Provisional application No. 63/797,985, filed on May 1, 2025.

(51) Int. Cl. H10P 90/00; G02B 6/42; H10P 50/00; H10W 10/10

(52) U.S. Cl. CPC H10P 90/1916; G02B 6/4243; H10P 50/691; H10W 10/181

(57) ABSTRACT

A method provides a silicon wafer having a front side and a back side, shapes the silicon wafer to have a silicon base at the back side and a silicon mandrel having a proximal end at the silicon base and a distal end at the front side, forms a ceramic wafer comprising the silicon wafer having the silicon mandrel, removes the silicon mandrel from the ceramic wafer to form a feature in a front side of the ceramic wafer, provides a donor silicon wafer having a front side and a back side, and bonds the back side of the donor silicon wafer to the front side of the ceramic wafer.

.

### CROSS-REFERENCE TO RELATED APPLICATIONS

This application claims priority to U.S. Provisional Patent Application No. 63/797,985, filed May 1, 2025, which is hereby incorporated by reference in its entirety for all purposes as if fully set forth herein.

### TECHNICAL FIELD

The present disclosure relates to interposers, in particular, amorphous polySiC ceramic interposers and wafers.

### BACKGROUND

Phased array beamformers and high-speed communication applications of the future drive development for substrates with low eddy currents like SiC interposers.

However, high speed data transmission can be limited by eddy current noise generated in silicon interposers. Use of SiC as an interposer but the material is expensive and it is expensive to form through-silicon vias (TSVs). SiC or AlN ceramic interposer are expensive and difficult to etch vias into. SiC interposers are expensive and etching thru vias in SiC is also expensive and time consuming. Ceramic interposers are also expensive to make and difficult to manufacture.

Existing solutions are based on the use of a standard silicon on insulation SOI wafer. The oxide box layer does not transfer heat efficiently, which can degrade system performance.

There is a need for ceramic interposers and wafers that are less expensive to manufacture and provide heat characteristics.

According to aspects, there is provided a method comprising: providing a silicon wafer having a front side and a back side; shaping the silicon wafer to have a silicon base at the back side and a silicon mandrel having a proximal end at the silicon base and a distal end at the front side; forming a ceramic wafer comprising the silicon wafer having the silicon mandrel; removing the silicon mandrel from the ceramic wafer to form a feature in a front side of the ceramic wafer; providing a donor silicon wafer having a front side and a back side; and bonding the back side of the donor silicon wafer to the front side of the ceramic wafer.

Aspects as in the preceding paragraph provides a method, wherein shaping the silicon wafer comprises: applying a photoresist pattern to the front side of the silicon wafer; and etching the silicon wafer through the photoresist pattern to remove exposed portions of the silicon wafer and form the silicon mandrel.

Aspects as in one of the preceding two paragraphs provides a method, wherein forming a ceramic wafer comprises: covering the front side of the silicon wafer having the silicon mandrel with a SiC powder; and heating and pressing the SiC powder into an amorphous polySiC ceramic.

Aspects as in one of the preceding three paragraphs provides a method, wherein removing the silicon mandrel from the ceramic wafer comprises washing the back side of the ceramic wafer with a fluid to dissolve the silicon base and the silicon mandrel.

Aspects as in one of the preceding four paragraphs provides a method, further comprising: implanting the back side of the donor silicon wafer to delineate a split face in the donor silicon wafer; and splitting the donor silicon wafer at the split face.

Aspects as in one of the preceding five paragraphs provides a method, wherein splitting comprises heating the donor silicon wafer.

Aspects as in one of the preceding six paragraphs provides a method, further comprising: applying a spin on glass layer to the back side of the donor silicon wafer.

Aspects as in one of the preceding seven paragraphs provides a method, wherein the spin on glass layer comprises particles having a relatively higher heat transfer coefficient than a material of the spin on glass layer.

Aspects as in one of the preceding eight paragraphs provides a method, wherein bonding the back side of the donor silicon wafer to the front side of the ceramic wafer comprises bonding the spin on glass layer to the front side of the ceramic wafer.

Aspects as in one of the preceding nine paragraphs provides a method, applying a thermal oxide layer on the donor silicon wafer.

According to aspects, there is provided a device comprising: a ceramic wafer having a front side and a back side, wherein the ceramic wafer comprises a SiC powder heated and pressed into an amorphous poly-SiC ceramic; a feature in a front side of the ceramic wafer; and a silicon layer bonded to the front side of the ceramic wafer.

Aspects as in the preceding paragraph provides a device, wherein the feature comprises a V-groove for a fiber optic cable.

Aspects as in one of the preceding two paragraphs provides a device, wherein a thickness of the silicon layer is between 1.5 and 2.0 µm.

Aspects as in one of the preceding three paragraphs provides a device, comprising a spin on glass layer between the ceramic wafer and the silicon layer, wherein the silicon layer is bonded to the front side of the ceramic wafer by being bonded to the spin on glass layer.

Aspects as in one of the preceding four paragraphs provides a device, wherein the spin on glass layer comprises particles having a relatively higher heat transfer coefficient than a material of the spin on glass layer.

Aspects as in one of the preceding five paragraphs provides a device, wherein a thickness of the spin on glass layer is between 2 and 20 µm, and the particles have a diameter dimension between .1 and 10 µm.

According to aspects, there is provided a system comprising: a ceramic wafer having a front side and a back side, wherein the ceramic wafer comprises a SiC powder heated and pressed into an amorphous poly-SiC ceramic; a V-groove in a front side of the ceramic wafer; a silicon layer bonded to the front side of the ceramic wafer, wherein the silicon layer comprises a transistor; and a photonic device attached to the ceramic wafer and in communication with a fiber optic cable, wherein the fiber optic cable is positioned in the V-groove.

Aspects as in one of the preceding two paragraphs provides a system, comprising a spin on glass layer between the ceramic wafer and the silicon layer, wherein the silicon layer is bonded to the front side of the ceramic wafer by being bonded to the spin on glass layer.

Aspects as in one of the preceding three paragraphs provides a system, wherein the spin on glass layer comprises particles having a relatively higher heat transfer coefficient than a material of the spin on glass layer.

Aspects as in one of the preceding four paragraphs provides a system, wherein the spin on glass layer comprises a waveguide and the ceramic wafer comprises an air gap proximate the waveguide.

### BRIEF DESCRIPTION OF THE DRAWINGS

A more complete understanding of the disclosure and the advantages thereof may be acquired by referring to the following description, taken in conjunction with the accompanying drawings and wherein:

FIG. 1 shows a cross-sectional, side view of a photonics package having a poly-SiC substrate and a diamondized (with heat transfer nanoparticles) spin on glass (SOG) layer.

FIG. 2A shows a cross-sectional side view of a silicon wafer before pattern features are therein formed.

FIG. 2B shows a cross-sectional side view of the silicon wafer of FIG. 2A, wherein a photoresist pattern is applied to the silicon wafer and then the silicon wafer is etched through the photoresist pattern to produce a “negative” of the pattern features desired for a pressed ceramic wafer.

FIG. 2C shows a cross-sectional side view of the silicon wafer of FIG. 2B, wherein the photoresist pattern is removed from the silicon mandrels.

FIG. 2D shows a cross-sectional side view of a donor silicon wafer before processing.

FIG. 2E shows a cross-sectional side view of the donor silicon wafer of FIG. 2D, wherein ions are implanted to a defined a split face.

FIG. 2F shows a cross-sectional side view of the donor silicon wafer of FIG. 2E, wherein a diamondized SOG layer is applied to the donor silicon wafer.

FIG. 2G shows a cross-sectional side view of the donor silicon wafer of FIG. 2F and the amorphous polySiC ceramic of FIG. 2C, wherein the donor silicon wafer is flipped up-side-down so that the diamondized SOG layer is positioned for contact with the patterned side of the amorphous polySiC ceramic.

FIG. 2H shows a cross-sectional side view of the donor silicon wafer and the amorphous polySiC ceramic of FIG. 2G, wherein the donor silicon wafer is fusion bonded to the diamondized SOG layer of the amorphous polySiC ceramic.

FIG. 2I shows a cross-sectional side view of the bonded donor silicon wafer and the amorphous polySiC ceramic of FIG. 2H, wherein the donor silicon wafer is split so a silicon layer remains to produce a polySiC ceramic wafer.

FIG. 3A shows a cross-sectional side view of a donor silicon wafer before processing.

FIG. 3B shows a cross-sectional side view of the donor silicon wafer of FIG. 3A, wherein it is ion planted to define a split face and a thermal oxide layer is applied.

FIG. 3C shows a cross-sectional side view of the donor silicon wafer of FIG. 3B, wherein the thermal oxide layer is etched through a photoresist.

FIG. 3D shows a cross-sectional side view of the donor silicon wafer of FIG. 3C, wherein a diamondized SOG layer is applied.

FIG. 3E shows a cross-sectional side view of the donor silicon wafer of FIG. 3D and an amorphous polySiC ceramic.

FIG. 3F shows a cross-sectional side view of the donor silicon wafer and the amorphous polySiC ceramic of FIG. 3E, wherein they are fusion bonded to produce a polySiC ceramic wafer having a thermal oxide layer.

FIG. 4 shows a flow chart of a method for producing a temperature tolerant polySiC ceramic wafer.

The drawings accompanying and forming part of this specification are included to depict certain aspects of the disclosure. The reference number for any illustrated element that appears in multiple different figures has the same meaning across the multiple figures, and the mention or discussion herein of any illustrated element in the context of any particular figure also applies to each other figure, if any, in which that same illustrated element is shown. The features illustrated in the drawings are not necessarily drawn to scale. It should be noted that the features illustrated in the drawings are not necessarily drawn to scale.

### DESCRIPTION

According to aspects, there is provided a structure using a mandrel defined poly-SiC base wafer and heat transfer enhanced diamondized SOG as a base for silicon photonics. This may allow heat to be efficiently removed from the system where the standard solution which has a standard silicon on insulation (SOI) BOX layer blocks heat from transferring.

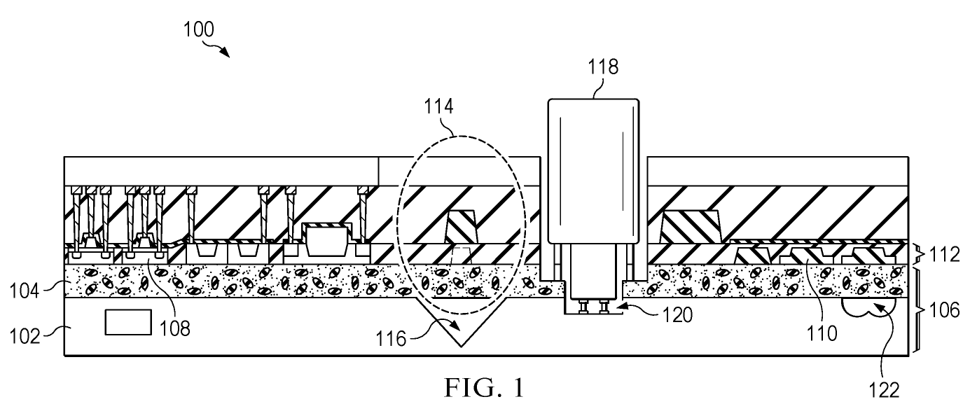

FIG. 1 shows a cross-sectional, side view of a photonics package 100 having a poly-SiC substrate 102 and a diamondized (with heat transfer nanoparticles) spin on glass (SOG) layer 104. The photonics package 100 has a temperature tolerant polySiC ceramic wafer 106. Transistors 108 and wave guides 110 are formed in a silicon layer 112. A single mode fiber (SMF) optic cable 114 is positioned in a V-groove 116 formed in the poly-SiC substrate 102. A photonic device 118, such as a laser, is positioned in the pad site 120 for a photonic device 118. An air gap 122 is provided adjacent wave guides 110 so as to regulate temperature via air circulation through the air gap 122.

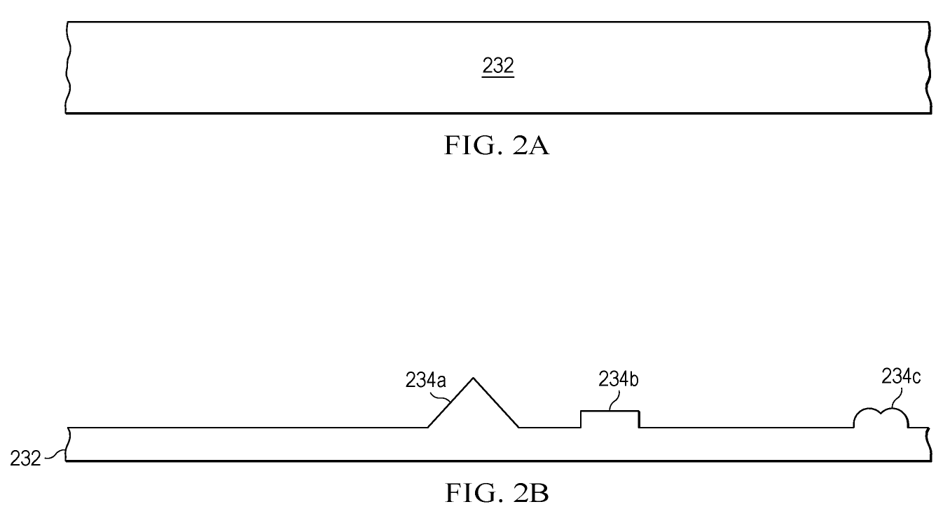

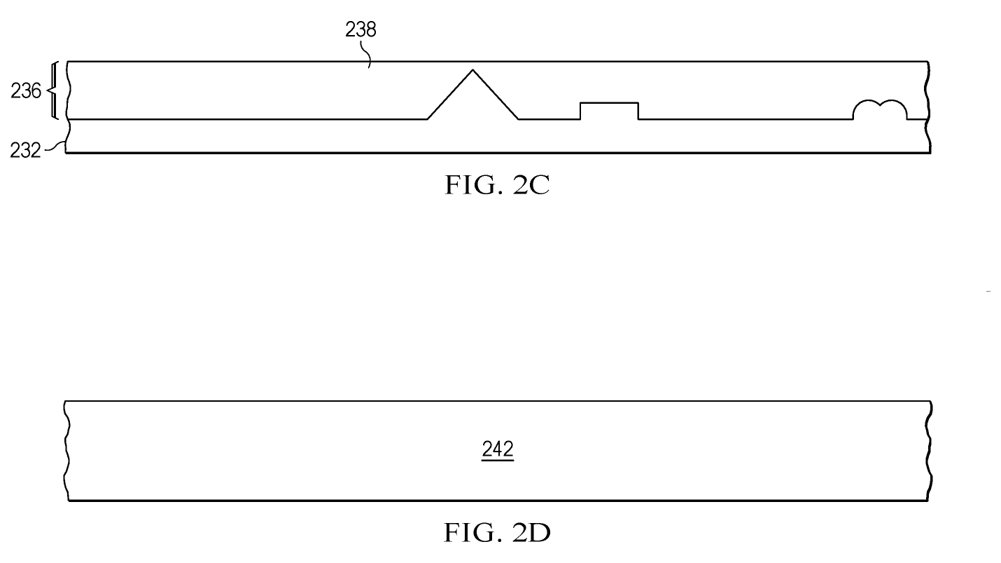

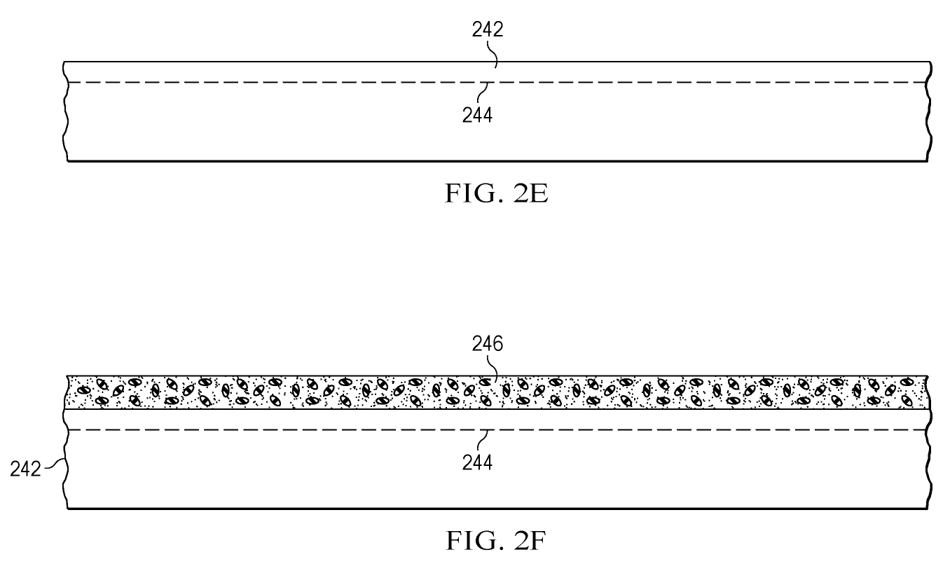

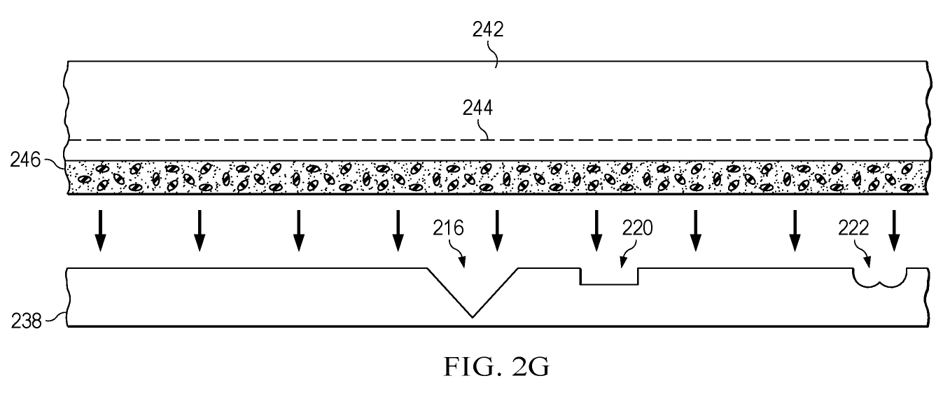

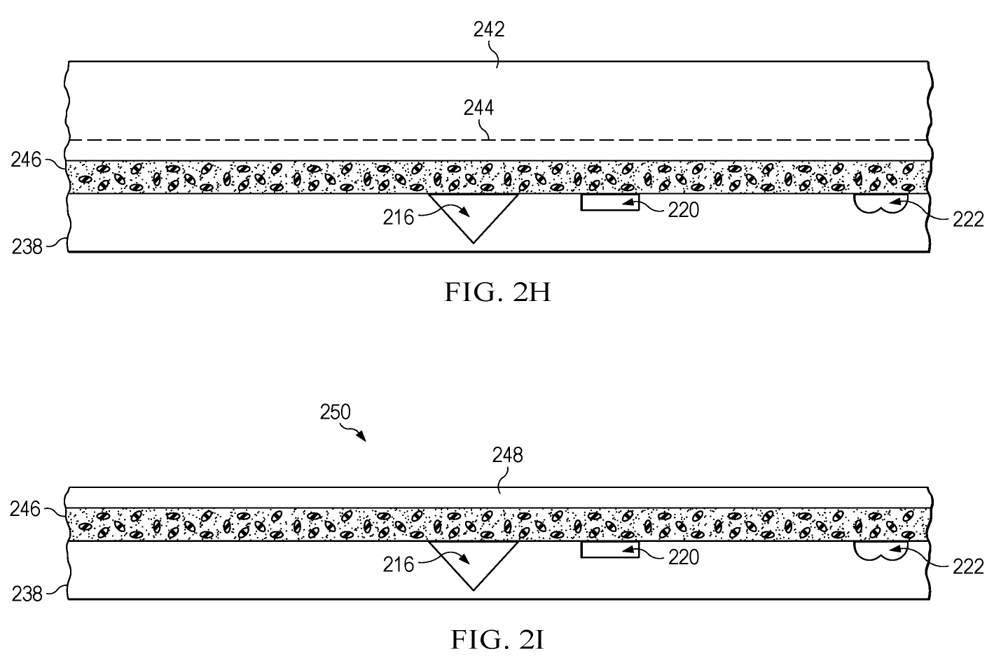

FIGS. 2A – 2I show fabrication of a pressed ceramic wafer having patterned features. According to aspects, there is provided a process of creating a ceramic wafer 106. The process is to create a ceramic wafer 106 using a pressed ceramic verses starting with a single crystal substrate. A silicon donor wafer has applied thereto a diamondized (with heat transfer nano-particles) Spin on Glass layer for improved heat transfer. A silicon mandrel is provided and a process is used to press SiC power to form the location of a V-groove for a fiber optic cable. Use of pressed poly-SiC (powder) to form the wafer. The wafer is processed and then the mandrel is removed. The etch is then finished to make the V-groove. This process may provide a less expensive wafer substrate with a V-groove that has good heat transfer characteristics.

FIG. 2A shows a cross-sectional side view of a silicon wafer 232 before pattern features are therein formed.

FIG. 2B shows a cross-sectional side view of the silicon wafer 232 of FIG. 2A. A photoresist pattern (not shown) is applied to the silicon wafer 232 and then the silicon wafer 232 is etched through the photoresist pattern to produce a “negative” of the pattern features desired for a pressed ceramic wafer. In this example, a “negative” mandrel 234a for a V-groove for a fiber optic cable is patterned, a “negative” mandrel 234b for a pad site for a photonic device is patterned, and a “negative” mandrel 234c for an air gap for air circulation is patterned. The silicon wafer 232 is etched to produce silicon mandrels 234. The silicon mandrels 234 may have a height of 100-600 µm and a width of 50-500 µm. The etch process may be a reactive-ion etch process. Rather than photoresist and etch, the silicon mandrels 234 may comprise tall silicon dots stacked to form a column or mandrel. Thin Si₃N₄ separation may be obtained with polycrystalline silicon carbide (pSiC).

FIG. 2C shows a cross-sectional side view of the silicon wafer 232 of FIG. 2B. The photoresist pattern is removed from the silicon mandrels 234. A thin silicon nitride film (not shown) may then optionally be deposited. The silicon mandrels 234 are covered with a SiC powder 236 and hot pressed to form an amorphous polySiC ceramic 238. The silicon wafer 232 is wet removed to dissolve it from the amorphous polySiC ceramic 238. Thus, an amorphous polySiC ceramic 238 is formed using silicon mandrels and pressed ceramic.

FIG. 2D shows a cross-sectional side view of a donor silicon wafer 242 before processing.

FIG. 2E shows a cross-sectional side view of the donor silicon wafer 242 of FIG. 2D. An ion implanter (not shown) is used to hydrogen implant to a defined depth where a split will occur at a split face (dotted line) 244. The depth of the split face (dotted line) 244 may be 1.5 – 2.0 µm.

FIG. 2F shows a cross-sectional side view of the donor silicon wafer 242 of FIG. 2E. A diamondized SOG layer 246 is applied to the donor silicon wafer 242. The diamondized SOG layer 246 may be a diamondized (with heat transfer nanoparticles) spin on glass (SOG) layer, wherein the particle size may be .1 – 10 µm. The thickness of the diamondized SOG layer 246 may be 2 – 20 µm. The donor silicon wafer 242 may be annealed at a temperature of about 450 °C to vaporize the organics out of the diamondized SOG layer 246 without splitting the donor silicon wafer 242, i.e., the anneal temperature is less than a fracture temperature.

FIG. 2G shows a cross-sectional side view of the donor silicon wafer 242 of FIG. 2F and the amorphous polySiC ceramic 238 of FIG. 2C. Both the donor silicon wafer 242 and the amorphous polySiC ceramic 238 are flipped up-side-down so that the diamondized SOG layer 246 of the donor silicon wafer 242 is positioned for contact with the patterned side of the amorphous polySiC ceramic 238. The donor silicon wafer 242 and the amorphous polySiC ceramic 238 are aligned for bonding.

FIG. 2H shows a cross-sectional side view of the donor silicon wafer 242 and the amorphous polySiC ceramic 238 of FIG. 2G. The donor silicon wafer 242 and the amorphous polySiC ceramic 238 are fusion bonded at the interface between the diamondized SOG layer 246 of the donor silicon wafer 242 and the patterned side of the amorphous polySiC ceramic 238.

FIG. 2I shows a cross-sectional side view of the bonded donor silicon wafer 242 and the amorphous polySiC ceramic 238 of FIG. 2H. The wafer/ceramic is annealed to about 900 °C to 1000 °C to fracture or split the donor silicon wafer 242 at the split face (dotted line) 244 (see FIG. 2H), so that a silicon layer 248 of about 1.5 – 2.0 µm remains with the diamondized SOG layer 246 bonded to the amorphous polySiC ceramic 238. The resulting product is a temperature tolerant polySiC ceramic wafer 250. The polySiC ceramic wafer 250 has a V-groove 216, a pad site 220, and an air gap 222 in the amorphous polySiC ceramic 238. The polySiC ceramic wafer 250 also has a diamondized SOG layer 246 and a silicon layer 248.

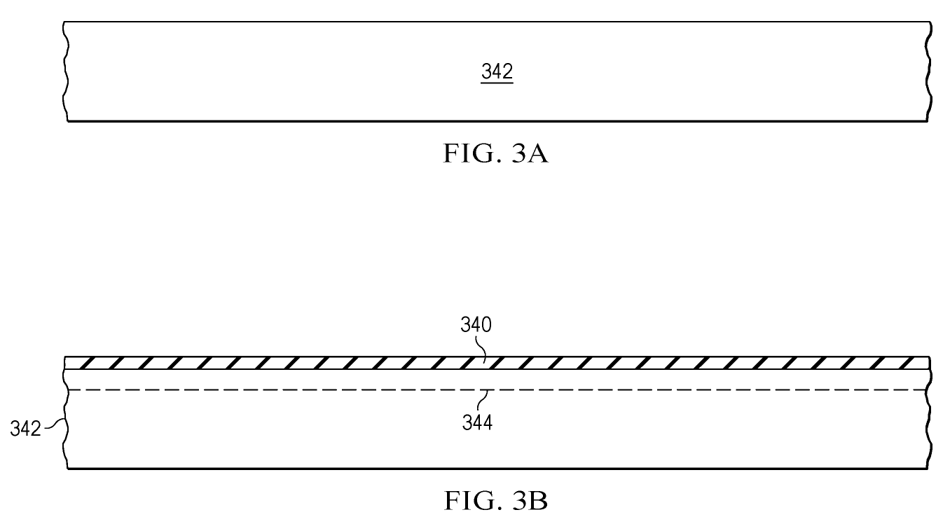

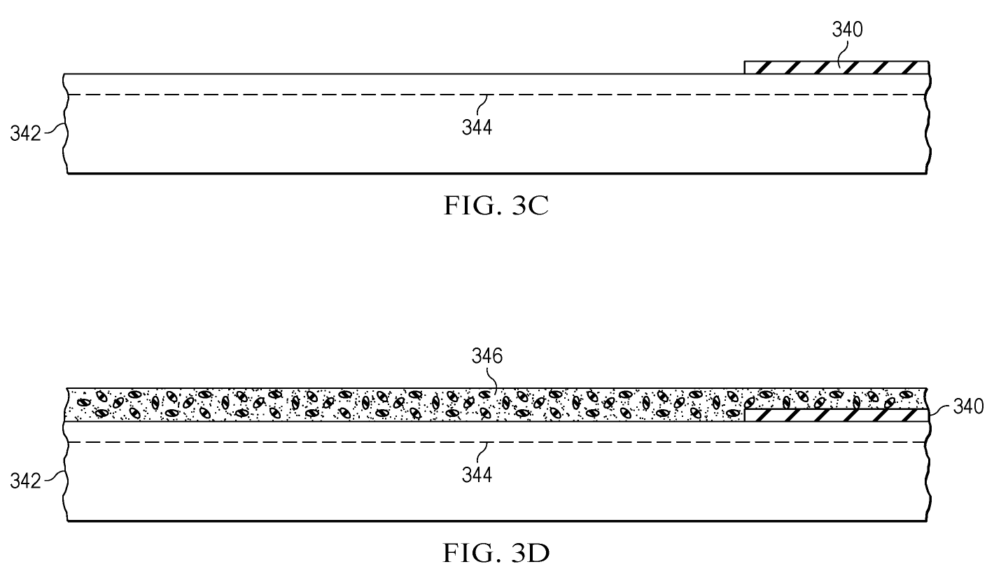

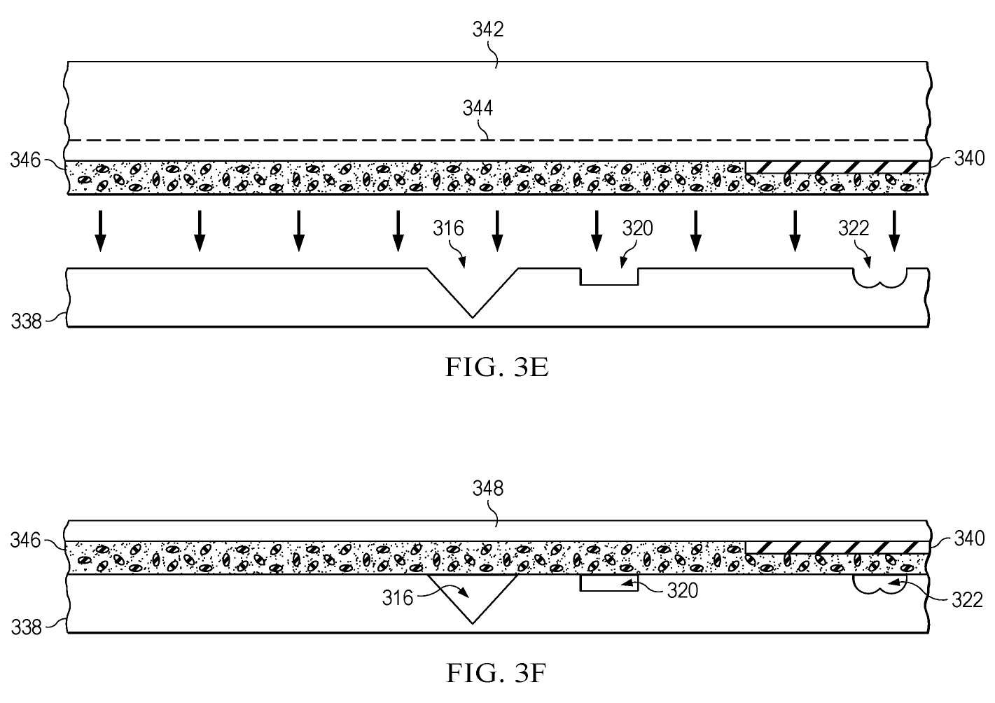

FIGS. 3A – 3F show fabrication of a polySiC ceramic wafer having patterned features and a thermal oxide layer.

FIG. 3A shows a cross-sectional side view of a donor silicon wafer 342 before processing.

FIG. 3B shows a cross-sectional side view of the donor silicon wafer 342 of FIG. 3A. An ion implanter (not shown) is used to hydrogen implant to a defined depth where a split will occur at a split face (dotted line) 344. The depth of the split face (dotted line) 344 may be 1.5 – 2.0 µm. A thermal oxide layer 340 is thermally grown or deposited on the implanted side of the donor silicon wafer 342.

FIG. 3C shows a cross-sectional side view of the donor silicon wafer 342 of FIG. 3B. A pattern photoresist (not shown) is applied to the thermal oxide layer 340. The thermal oxide layer 340 is etched through the pattern photoresist so that the remaining thermal oxide layer 340 is located where it is desired to retain heat. The pattern photoresist is removed.

FIG. 3D shows a cross-sectional side view of the donor silicon wafer 342 of FIG. 3C. A diamondized SOG layer 346 is applied to the donor silicon wafer 342. The diamondized SOG layer 346 may be a diamondized (with heat transfer nanoparticles) spin on glass (SOG) layer, wherein the particle size may be .1 – 10 µm. The thickness of the diamondized SOG layer 346 may be 2 – 20 µm. The donor silicon wafer 342 may be annealed at a temperature of about 450 °C to vaporize the organics out of the diamondized SOG layer 346 without fracturing or splitting the donor silicon wafer 342.

FIG. 3E shows a cross-sectional side view of the donor silicon wafer 342 and an amorphous polySiC ceramic 338. Both the donor silicon wafer 342 and the amorphous polySiC ceramic 338 are flipped up-side-down so that the diamondized SOG layer 346 is positioned for contact with the patterned side of the amorphous polySiC ceramic 338. The thermal oxide layer 340 is positioned adjacent the air gap 322 in the amorphous polySiC ceramic 338.

FIG. 3F shows a cross-sectional side view of the donor silicon wafer 342 and the amorphous polySiC ceramic 338 of FIG. 3E. The donor silicon wafer 342 and the amorphous polySiC ceramic 338 are fusion bonded. The wafer/ceramic is annealed to about 900 °C to 1000 °C to fracture or split the donor silicon wafer 342 at the split face (dotted line) 344 (see FIG. 3E), so that a silicon layer 348 of about 1.5 – 2.0 µm remains with the diamondized SOG layer 346 bonded to the amorphous polySiC ceramic 338. The resulting product is a temperature tolerant polySiC ceramic wafer 350 having a thermal oxide layer 340.

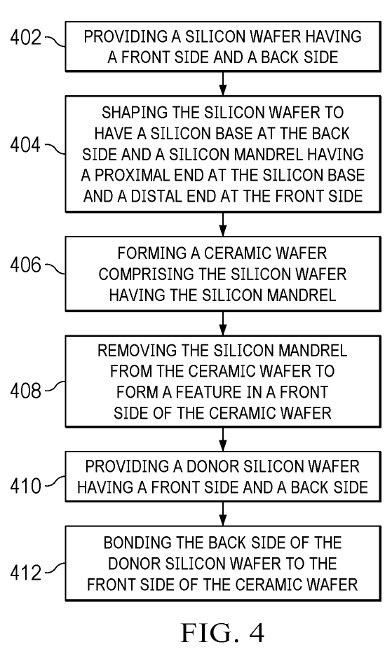

FIG. 4 shows a flow chart of a method for producing a temperature tolerant polySiC ceramic wafer. A silicon wafer is provided 402 having a front side and a back side. The silicon wafer is shaped 404 to have a silicon base at the back side and a silicon mandrel having a proximal end at the silicon base and a distal end at the front side. A ceramic wafer is formed 406 comprising the silicon wafer having the silicon mandrel. The silicon mandrel is removed 408 from the ceramic wafer to form a feature in a front side of the ceramic wafer. A donor silicon wafer is provided 410 having a front side and a back side. The back side of the donor silicon wafer is bonded 412 to the front side of the ceramic wafer.

Although examples have been described above, other variations and examples may be made from this disclosure without departing from the spirit and scope of these disclosed examples.

What is claimed is:

1. A method comprising:
providing a silicon wafer having a front side and a back side;
shaping the silicon wafer to have a silicon base at the back side and a silicon mandrel having a proximal end at the silicon base and a distal end at the front side;
forming a ceramic wafer comprising the silicon wafer having the silicon mandrel;
removing the silicon mandrel from the ceramic wafer to form a feature in a front side of the ceramic wafer;
providing a donor silicon wafer having a front side and a back side; and
bonding the back side of the donor silicon wafer to the front side of the ceramic wafer.

2. The method as in claim 1, wherein shaping the silicon wafer comprises:
applying a photoresist pattern to the front side of the silicon wafer; and
etching the silicon wafer through the photoresist pattern to remove exposed portions of the silicon wafer and form the silicon mandrel.

3. The method as in claim 1, wherein forming a ceramic wafer comprises:
covering the front side of the silicon wafer having the silicon mandrel with a SiC powder; and
heating and pressing the SiC powder into an amorphous polySiC ceramic.

4. The method as in claim 1, wherein removing the silicon mandrel from the ceramic wafer comprises washing the back side of the ceramic wafer with a fluid to dissolve the silicon base and the silicon mandrel.

5. The method as in claim 1, further comprising:
implanting the back side of the donor silicon wafer to delineate a split face in the donor silicon wafer; and
splitting the donor silicon wafer at the split face.

6. The method as in claim 5, wherein splitting comprises heating the donor silicon wafer.

7. The method as in claim 1, further comprising:
applying a spin on glass layer to the back side of the donor silicon wafer.

8. The method as in claim 7, wherein the spin on glass layer comprises particles having a relatively higher heat transfer coefficient than a material of the spin on glass layer.

9. The method as in claim 7, wherein bonding the back side of the donor silicon wafer to the front side of the ceramic wafer comprises bonding the spin on glass layer to the front side of the ceramic wafer.

10. The method as in claim 1, applying a thermal oxide layer on the donor silicon wafer.

11. A device comprising:
a ceramic wafer having a front side and a back side, wherein the ceramic wafer comprises a SiC powder heated and pressed into an amorphous poly-SiC ceramic;
a feature in a front side of the ceramic wafer; and
a silicon layer bonded to the front side of the ceramic wafer.

12. The device as in claim 11, wherein the feature comprises a V-groove for a fiber optic cable.

13. The device as in claim 11, wherein a thickness of the silicon layer is between 1.5 and 2.0 µm.

14. The device as in claim 11, comprising a spin on glass layer between the ceramic wafer and the silicon layer, wherein the silicon layer is bonded to the front side of the ceramic wafer by being bonded to the spin on glass layer.

15. The device as in claim 14, wherein the spin on glass layer comprises particles having a relatively higher heat transfer coefficient than a material of the spin on glass layer.

16. The device as in claim 15, wherein a thickness of the spin on glass layer is between 2 and 20 µm, and the particles have a diameter dimension between .1 and 10 µm.

17. A system comprising:
a ceramic wafer having a front side and a back side, wherein the ceramic wafer comprises a SiC powder heated and pressed into an amorphous poly-SiC ceramic;
a V-groove in a front side of the ceramic wafer;
a silicon layer bonded to the front side of the ceramic wafer, wherein the silicon layer comprises a transistor; and
a photonic device attached to the ceramic wafer and in communication with a fiber optic cable, wherein the fiber optic cable is positioned in the V-groove.

18. The system as in claim 17, comprising a spin on glass layer between the ceramic wafer and the silicon layer, wherein the silicon layer is bonded to the front side of the ceramic wafer by being bonded to the spin on glass layer.

19. The system as in claim 18, wherein the spin on glass layer comprises particles having a relatively higher heat transfer coefficient than a material of the spin on glass layer.

20. The system as in claim 18, wherein the spin on glass layer comprises a waveguide and the ceramic wafer comprises an air gap proximate the waveguide.
